(19) United States
(12) Patent Application Publication
(10) Pub. No.: US 2012/0160299 A1
(43) Pub. Date: Jun. 28, 2012

(54) Solar Cell Array For Use In Aerospace Application, And A Method Of Assembly Thereof

(75) Inventors: Austin Daniel Reid, San Diego, CA (US); Theodore Garry Stern, El Cajon, CA (US); Eric Peter McNaul, San Diego, CA (US)

(73) Assignee: DR Technologies, Inc.

(21) Appl. No.: 12/980,198

(22) Filed: Dec. 28, 2010

(51) Int. Cl. H01L 31/048; H01L 31/18; H01L 31/052

(52) U.S. Cl. 136/246; 438/67; 257/E31.11

(57) ABSTRACT

A space based solar array has a substrate on which are placed a plurality of spaced apart solar cells. A transparent adhesive bonding layer is on the plurality of solar cells covering the solar cells and the substrate between said solar cells. In a preferred embodiment, the adhesive bonding layer is silicone. A transparent rigid buffer layer is on the transparent adhesive bonding layer. In a preferred embodiment, the transparent rigid buffer layer is made of polyimide and has properties suitable for the application of performance- or durability-enhancing thin-film coatings. A transparent thin-film stack including inorganic radiation protection layer is on the transparent rigid buffer layer. In a preferred embodiment, the transparent radiation protection layer is made of silica, alumina or thin glass. Performance enhancing layers can also be included into the thin film stack for anti-reflection and ESD control purposes.

### TECHNICAL FIELD

The present invention relates to a solar cell array and, more particularly, to a solar cell array that is well suited for use in harsh aerospace environments for application in supplying power for aero and space vehicles. The present invention also relates to a method of assembling such a solar cell array.

### BACKGROUND OF THE INVENTION

Solar cell arrays are well known in the art. Solar cell arrays have been manufactured for use in terrestrial applications as well as aerospace applications including use at high altitude atmospheric environments, in earth orbital environments, and in interplanetary, lunar, and planetary environments. For solar cell arrays that are intended for terrestrial application, however, the solar cell arrays do not have to withstand these more hazardous environments.

Referring to FIG. 1 there is shown a cross sectional view of a solar cell array 10 of the prior art for use in aerospace applications. The array 10 comprises a substrate 12 on which are placed a plurality of solar cells 14 arranged in an array. The cells 14 are spaced apart from one another. A coverglass 16 is bonded to each cell 14. The coverglass 16 provides protection for the solar cell 14, and along with the associate interconnect connects to other cells 14. Thus, during manufacturing, the solar cells 14 are fabricated, followed by the coverglass 16 bonded thereto, and then formed into a Cell Interconnect-Coverglass (CIC) assembly. The CIC assemblies are then electrically strung together with the entire assembly subsequently laid down on the substrate 12 in a separate silicone bonding operation. The assembly then appears as a tiled array of CICs with spaces between each cell 14 which can expose the insulating layers and the cell-to-cell interconnects to the external environments. For extremely thin cells 14, which is desirable from a weight perspective for extra-terrestrial application, supporting the CICs and the stringing process can be problematic and can lead to cell breakage and loss of performance. Of course, the coverglass 16, especially for extra-terrestrial application must protect the cell 14 from the harmful and hazardous radiation and particles of outer space.

In another solar cell array of the prior art, especially suited for terrestrial use, the solar cells 14 are covered by a single laminated transparent coating, often fabricated from thick glass, polycarbonate plastic, or Tedlar (a registered trademark of E. I. Du Pont De Nemours and Company Corporation). However for aerospace vehicle application, the thickness and weight is a particular drawback. In addition, Tedlar does not remain transparent due to UV radiation and particulates (such as electrons and photons) found in the aerospace environments.

Finally, for aerospace applications, solar cell arrays must be thin, light weight, and can be folded into a compact array and stowed during launch and then deployed in space. Thus, thin film solar cells such as Inverted Metamorphic (IMM) solar cells have been manufactured (for example by Boeing Corporation's Spetrolab subsidiary or Emcore Photovoltaics) for use in arrays for use in these aerospace applications. Current manufacturing process using crystalline based solar cells rely on the solar cells and interconnect to support themselves during the assembly on the substrate 12. However, this particular process does not work well for IMM type solar cells due to the brittleness and fragility of the solar cells.

Accordingly, it is one object of the present invention to provide a solar cell array that is an improvement in the manufacturability and durability of solar cell arrays, and which uses conventional high efficiency crystalline solar cells or thin solar cells such as IMM type cells, and is of low thickness and light weight, and can be manufactured to withstand the hazardous environment of outer space.

### SUMMARY OF THE INVENTION

A solar array comprises a substrate, upon which are bonded a plurality of solar cells spaced apart from one another. A transparent adhesive bonding layer is on the plurality of solar cells covering the solar cells and between the solar cells. A transparent buffer layer is on the transparent adhesive bonding layer. A protective film is on the buffer layer.

The present invention also relates to a method of manufacturing the foregoing described solar cell array.

### BRIEF DESCRIPTION OF THE DRAWINGS

FIG. 1 is a cross-sectional view of a solar cell array of the prior art.

FIG. 2 is a cross-sectional view of a solar cell array of the present invention.

FIG. 3 is a cross-sectional view of a laminated superstrate layer covering the solar cells in the array shown in FIG. 2.

FIG. 4 is a cross-sectional view of a laminated substrate layer upon which the solar cells are placed in the array shown in FIG. 2.

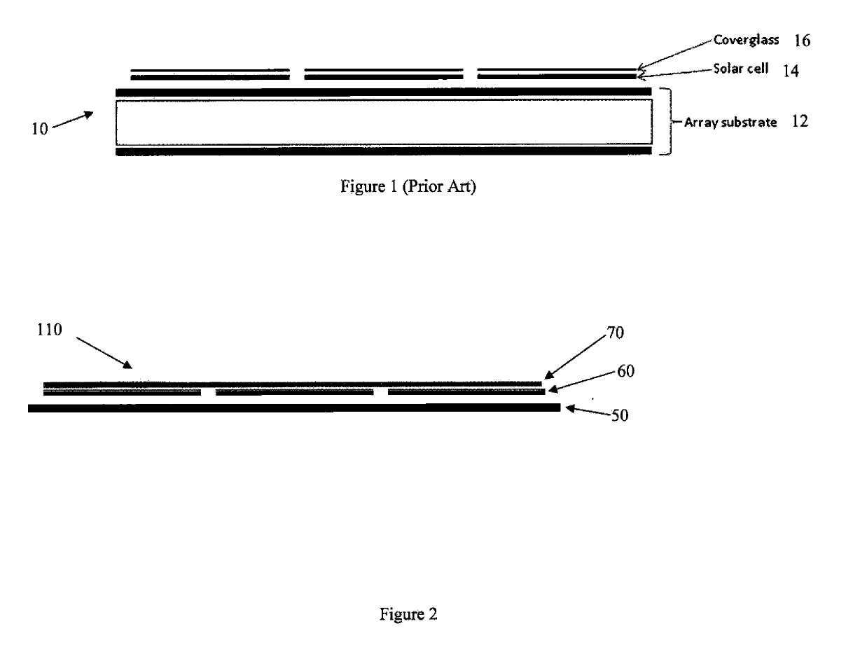

### DETAILED DESCRIPTION OF THE PREFERRED EMBODIMENT

Referring to FIG. 2 there is shown a cross-sectional view of a solar cell array 110 of the present invention. The array 110 comprises a plurality of spaced apart solar cells 60. The solar cells 60 can be of any of the conventional type such as single crystalline silicon based solar cells, III-V type solar cells such as triple junction cells typically used in space solar arrays and are 5-10 mils thick, or thin film high efficiency solar cells, such as Inverted Metamorphic IMM type cells that are typically less than 1-mil thick. In the preferred embodiment for aerospace application requirement for light weight, IMM solar cells are used. The cells 60 are placed on a superstrate 70 the details are which set forth hereinafter.

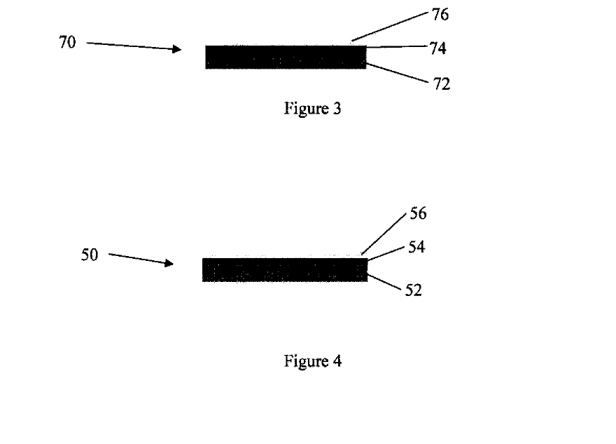

The superstrate 70 covers the plurality of solar cells 60 and covers portions of the substrate 50 between the cells 60 and around the perimeter of the array of solar cells 60. Thus, the superstrate 70 is an integrated laminate that covers all of the solar cells 60. The superstrate 60 is shown in greater detail in FIG. 3. A first layer 72 is a transparent adhesive bonding layer 72. In the preferred embodiment, the layer 72 is silicone. A second layer 74 covers the first layer 72 and provides a transparent rigid buffer layer 74. In the preferred embodiment it is made of polyimide 74. The polyimide layer 74 has a Coefficient of Thermal Expansion (CTE) lower than silicone and upon which it is suitable to apply performance- or durability-enhancing thin-film coating 76, which might otherwise crack when applied directly to the silicone adhesive bonding layer 72. Finally, a thin film coating 76, in the preferred embodiment a thin glass transparent radiation protection layer with optional thin-film or transparent conductive added layer 76 covers the second layer 74. The radiation protection layer 76 protects the solar cell array 110 from the direct impacts of various space hazards, such as atomic oxygen, space plasma, UV and particulate radiation (electrons and photons). In the preferred embodiment, the third layer 76 can be made from a stack of inorganic material such as silica, alumina, or other thin glass, salt or oxide layer. Finally, an optional fourth layer (not shown) of anti-reflective coating or transparent conductive oxide layer can be applied on the third layer 76 to provide additional performance or functionality. Preferably each of the layers 72, 74 and 76 is a layer having a cross-sectional thickness as thin as can be fabricated in raw material form and at a practical cost that still meets the durability and performance requirements. The silicone layer 72 is typically 2-10 mils (50-250 microns) thick, the polyimide layer 74 is typically 0.4-2 mils (10-50 microns) thick, and the thin film coating layer 76 is typically of negligible thickness, <0.04 mils (1 micron).

The cells 60 and the superstrate layer 70 are bonded to a substrate 50 using opaque adhesive. In the preferred embodiment this adhesive is a Room Temperature Vulcanizing opaque silicone adhesive such as NuSil CV-2568, which may be 2-10 mils thick. The substrate 50 shown in FIG. 4 also comprises a plurality of layers. A fifth layer 56 upon which the plurality of solar cells 60 are placed is an electrically insulating layer 56. The fifth layer 56 can be made of Kapton (a registered trademark of E. I. Du Pont De Nemours and Company Corporation). The fifth layer 56 covers an optional sixth layer 54. The optional sixth layer 54 can provide flexible electrical wiring between the solar cells 60 and routes the electrical signal from one location to another. The sixth layer 54 can be made of Kapton with copper wiring traces, as are commonly used in flexible electronic circuit boards. Finally, in the event a sixth layer 54 is used, the sixth layer 54 covers a seventh layer 52. Otherwise, in the absence of the sixth layer 54, the fifth layer 56 covers the seventh layer 52. The seventh layer 52 provides structural support for the solar cell array 110, and in the preferred embodiment is a thin layer of material with the same or similar coefficient of thermal expansion as the plurality of solar cells 60.

The present invention also relates to a method of manufacturing the foregoing described array of solar cells 110. In the method of the present invention, the superstrate 70 is first formed. The first layer 72 of silicone is optionally first formed with a plurality of cavities molded therein on one side of the first layer 72. The cavities can be holes through the material or partially through the material, as in a thin waffle-shaped structure. The cavities may be covered by the rigid buffer layer 74 such that the assembly of substrate 50, solar cells 60 superstrate 70 provides a set of enclosed cavities. In an embodiment using thicker cells 60, such as triple junction III-V cells 60, each of the cavities is spaced apart from one another and provides the cavity into which each solar cell 60 would be placed. Each cavity provides an index for the placement of each solar cell 60. In the preferred embodiment using IMM solar cells, cavities are provided in the layer of silicone 72 so as to provide an empty space in which to place cell to cell interconnection using wire-bonding techniques. On another side of the first layer 72 is formed the second layer 74 and the third layer 76 respectively. Once the superstrate 70 with the plurality of cavities are formed, the plurality of solar cells 60 are placed into the cavities of the superstrate 70 such that the cavities are positioned appropriately on the front side of each solar cell 60 (the side to receive the light). Once the solar cells 60 are placed into the cavities of the superstrate 70, the solar cells 60 can then be interconnected using conventional thermosonic bonded wire or ribbon. This is possible because each cell 60 is in a cavity with the cavity minimizing the movement of the cell 60 during the interconnect process. The assembled superstrate 70 with the solar cells 60 can then be bonded to the substrate 50 using an opaque silicone adhesive.

From the foregoing, it can be seen that a light weight solar cell array well suited for the hazardous environment of outer space and a method of assembling such an array is disclosed. In particular, with the solar cell array 110 of the present invention and the method of the present invention, there is no need for stiffening layers either in front of the cells 60 or behind the cells 60. The elimination of these layers and their associated mass and thickness provides flexibility for the array 110 as well as allows the efficient use of mass and thickness for protection from photonic and particulate radiations and thermal expansion coefficient differentials. The silicone layer 72 reduces the need for ionizing radiation protection and allows a thinner and potentially more flexible layers 74 and 76. Further, the fact that the superstrate 70 is a continuous layer decouples the top superstrate layer 70 from the solar cells 60 allowing any shape or type of shield, whether it is an organic film, sheet of glass or sheet of patterned, roughened or shaped glass or plastic.

What is claimed is:

1. A solar array comprising:
a substrate;
a plurality of solar cells spaced apart from one another and bonded onto said substrate;
a transparent adhesive bonding layer on said plurality of solar cells covering said solar cells and said substrate between said solar cells;
a transparent buffer layer on said transparent adhesive bonding layer; and
a transparent protective film over said transparent buffer layer.

2. The array of claim 1 wherein said buffer layer having a Coefficient of Thermal Expansion (CTE) lower than the CTE of the adhesive bonding layer.

3. The array of claim 1 further comprising:
a transparent anti-reflective coating on said transparent protective film.

4. The array of claim 1 wherein said protective film is made from an inorganic material.

5. The array of claim 4 wherein said inorganic material is a material chosen from silica, alumina or thin glass.

6. The array of claim 5 wherein said protective film comprises a stack of inorganic material.

7. The array of claim 1 wherein said transparent buffer layer is made from polyimide.

8. The array of claim 1 wherein said transparent adhesive bonding layer is made from silicone.

9. The array of claim 8 wherein said silicone is molded to provide an index for the placement of the solar cells.

10. The array of claim 8 wherein said silicone is molded to provide cavities for wire bonds between the plurality of solar cells

11. The array of claim 9 wherein said index comprises a plurality of cavities in said silicone for the placement of the solar cells,

12. The array of claim 1 wherein said substrate comprises a plurality of layers.

13. The array of claim 12 wherein said substrate further comprises:
a structural layer for providing structural support;
a flexible circuit electrical wiring layer on said structural layer;
an insulating layer on said flexible circuit electrical wiring layer, on which the plurality of solar cells are placed.

14. The array of claim 13 wherein said structural layer has substantially the same Coefficient of Thermal Expansion as said plurality of solar cells.

15. The array of claim 15 wherein said insulating layer is made from Kapton.

16. A method of manufacturing a solar cell array, said method comprising:
providing a substrate;
molding a superstrate having a layer of transparent adhesive bonding material, molded to provide a plurality of spaced apart cavities on one side, and a layer of transparent rigid buffer material on said layer of transparent adhesive bonding material on a side opposite the one side, and a transparent radiation protection layer on the layer of transparent rigid buffer layer;
placing a plurality of solar cells in said superstrate with a solar cell positioned in each cavity of said transparent adhesive bonding material, to form a resultant structure; and
placing said resultant structure on said substrate, with said one side of said transparent adhesive bonding material contacting said substrate.
